(19) United States
(12) Patent Application Publication
(10) Pub. No.: US 2024/0297060 A1
(43) Pub. Date: Sep. 5, 2024

(54) STORAGE APPARATUS FOR SEMICONDUCTOR DEVICES AND STORAGE SYSTEM INCLUDING THE SAME

(71) Applicant: SAMSUNG ELECTRONICS CO., LTD., Suwon-si (KR)

(72) Inventors: Youngon OH, Suwon-si (KR); Jihun KIM, Suwon-si (KR); Sanghyuk PARK, Suwon-si (KR)

(73) Assignee: SAMSUNG ELECTRONICS CO., LTD., Suwon-si (KR)

(21) Appl. No.: 18/531,025

(22) Filed: Dec. 6, 2023

(30) Foreign Application Priority Data
Mar. 2, 2023 (KR) 10-2023-0027560

(51) Int. Cl. H01L 21/677; B65G 1/04

(52) U.S. Cl. CPC H01L 21/67769; B65G 1/0464; H01L 21/6773; H01L 21/67733; H01L 21/67775

(57) ABSTRACT

In some embodiments, a storage apparatus for a plurality of semiconductor devices includes a plurality of frames stacked at least partially on top of one another in a vertical direction, a plurality of shelves provided to be slidably movable on the plurality of frames along at least one guide rail extending in a first horizontal direction, a coupling portion including first couplers and second couplers that are selectively engaged with each other by an external control signal, and a driving portion provided to be movable in the first horizontal direction along the at least one guide rail. The plurality of shelves are configured to accommodate the plurality of semiconductor devices on upper surfaces of the plurality of shelves. The first couplers are provided on a first side surface of the plurality of shelves, and the second couplers are provided on a second opposite side surface of the plurality of shelves.

### CROSS-REFERENCE TO RELATED APPLICATIONS

This application claims benefit of priority under 35 U.S.C. § 119 to Korean Patent Application No. 10-2023-0027560, filed on Mar. 2, 2023, in the Korean Intellectual Property Office, the disclosure of which is incorporated by reference herein in its entirety.

### BACKGROUND

### 1. Field

The present disclosure relates generally to semiconductor devices, and more particularly, to a storage apparatus for semiconductor devices for storing a plurality of semiconductor elements and a storage system including the same.

### 2. Description of Related Art

Related semiconductor process equipment for manufacturing semiconductor devices may use ground type stockers capable of temporarily storing the semiconductor devices. The semiconductor devices accommodated in the ground type stockers may be transported by an overhead hoist transport (OHT) installed on the ground type stockers. For example, in order to transport the semiconductor device to the overhead hoist transport, the ground type stocker may slide a carrier that stores the semiconductor devices to the front side of the stocker and the OHT may move downward to grip the carrier exposed to the OHT. However, a storage capacity of the ground type stocker may be reduced in order to secure a space for exposing the semiconductor device. Alternatively or additionally, the storage capacity of the ground type stocker may be reduced to secure installation space for equipment that may expose the semiconductor devices. In addition, a safety accident may occur in a process of installing a crane of the ground type stockers.

### SUMMARY

Aspects of the present disclosure may provide a storage apparatus that may improve storage capacity of semiconductor devices and/or may reduce and/or prevent safety accidents, when compared to related storage apparatuses.

Aspects of the present disclosure may provide a storage system including the storage apparatus.

According to an aspect of the present disclosure, a storage apparatus for a plurality of semiconductor devices is provided. The storage apparatus includes a plurality of frames stacked at least partially on top of one another in a vertical direction. Each frame of the plurality of frames includes at least one guide rail extending in a first horizontal direction. The storage apparatus further includes a plurality of shelves provided to be slidably movable on the plurality of frames along the at least one guide rail. Each shelf of the plurality of shelves is configured to accommodate a portion of the plurality of semiconductor devices on an upper surface of the shelf. The storage apparatus further includes a coupling portion including first couplers and second couplers that are selectively engaged with each other by an external control signal. The first couplers are provided on a first side surface of each shelf of the plurality of shelves. The second couplers are provided on a second side surface of each shelf of the plurality of shelves. The second side surface is opposite to the first side surface. The first side surface and the second side surface extend along a second horizontal direction perpendicular to the first horizontal direction. The storage apparatus further includes a driving portion provided to be movable in the first horizontal direction along the at least one guide rail. The driving portion is configured to grip at least one selected shelf from among the plurality of shelves and to move, in the first horizontal direction, one or more shelves that are engaged to each other by respective first couplers and respective second couplers. The one or more shelves include the at least one selected shelf.

According to an aspect of the present disclosure, a storage system for a plurality of semiconductor devices is provided. The storage system includes a driving rail extending in a first horizontal direction and a storage apparatus extending along the driving rail. The storage apparatus is configured to accommodate the plurality of semiconductor devices. The storage system further includes a transport device movable on the driving rail. The transport device is configured to load the plurality of semiconductor devices to the storage apparatus and to unload the plurality of semiconductor devices from the storage apparatus. The storage apparatus further includes a plurality of frames stacked at least partially on top of one another in a vertical direction. Each frame of the plurality of frames includes at least one guide rail extending in the first horizontal direction. Each frame of the plurality of frames includes an opening portion opened in the vertical direction. The transport device is configured to pass through the opening portion to move between the plurality of frames. The storage apparatus further includes a plurality of shelves provided to be slidably movable on the plurality of frames along the at least one guide rail. Each shelf of the plurality of shelves is configured to accommodate a portion of the plurality of semiconductor devices on an upper surface of the shelf. The storage apparatus further includes a coupling portion including first couplers and second couplers that are selectively engaged with each other by an external control signal. The first couplers are provided on a first side surface of each shelf of the plurality of shelves. The second couplers are provided on a second side surface of each shelf of the plurality of shelves. The second side surface is opposite to the first side surface. The first side surface and the second side surface extend along a second horizontal direction perpendicular to the first horizontal direction. The storage apparatus further includes a driving portion provided to be movable in the first horizontal direction along the at least one guide rail. The driving portion is configured to grip at least one selected shelf from among the plurality of shelves and to move, in the first horizontal direction, one or more shelves that are engaged to each other by respective first couplers and respective second couplers. The one or more shelves include the at least one selected shelf.

According to an aspect of the present disclosure, a storage apparatus for a plurality of semiconductor devices is provided. The storage apparatus includes a plurality of frames. Each frame of the plurality of frames includes a guide rail extending in a horizontal direction and a driving portion movable along the guide rail. The plurality of frames are stacked at least partially on top of each other in a vertical direction. The storage apparatus further includes a plurality of shelves configured to accommodate the plurality of semiconductor devices on upper surfaces of the plurality of shelves. The plurality of shelves is configured to be slidably movable along the guide rail through the driving portion of each frame of the plurality of frames. Each shelf of the plurality of shelves includes a permanent magnet on a first side surface and an electromagnet on a second side surface opposite to the first side surface. The storage apparatus further includes a gas supply portion that includes a plurality of gas supply pipes coupled to the plurality of shelves and is configured to supply a purge gas to the plurality of semiconductor devices. One or more shelves selected from among the plurality of shelves disposed adjacent to each other are engaged to each other through the permanent magnet and the electromagnet to slidably move together in the horizontal direction. A plurality of second shelves disposed on the one or more selected shelves slidably move in the horizontal direction together with the one or more selected shelves.

As described above, the plurality of shelves of the storage apparatus may move in the horizontal direction along the guide rail through the drive portion on the plurality of frames. For example, the engaged shelves (e.g., the selected shelves), from among the plurality of shelves, may move together in the horizontal direction. When the engaged shelves move together in the horizontal direction and the plurality of frames have openings exposed upward, the storage apparatus may expose the semiconductor device to be transported in the vertical direction. Consequently, the shelves may not interfere with a movement path of an overhead hoist transport (OHT), and the OHT may pass through the plurality of frames. Furthermore, the storage apparatus may not require space or additional devices for exposing the semiconductor device, and thus, space utilization of the storage apparatus may be improved, when compared to related storage apparatuses.

In addition, the storage apparatus, according to the present disclosure may be implemented without a crane structure for exposing the semiconductor devices to the OHT. Accordingly, safety accidents that may occur in a process of installing the crane structure may be prevented.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIG. 1 is a perspective view illustrating a storage system for semiconductor devices, according to an embodiment;

FIG. 2 is a perspective view illustrating the driving rail and the transport device in FIG. 1, according to an embodiment;

FIG. 3 is a perspective view illustrating a plurality of shelves provided on the frame in FIG. 1, according to an embodiment;

FIG. 4 is a perspective view illustrating the frame in FIG. 3, according to an embodiment;

FIGS. 5 and 6 are perspective views illustrating one of the plurality of shelves in FIG. 3, according to an embodiment;

FIG. 7 is a perspective view illustrating the gas supply portion in FIG. 3, according to an embodiment;

FIGS. 8 to 12 are views illustrating a process of unloading a semiconductor device from a storage system, according to an embodiment; and

FIGS. 13 to 16 are views illustrating a process of loading a semiconductor device onto a storage system, according to an embodiment.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, and the like may be replaced with terms, such as “first,” “second,” third” to be used to describe relative positions of elements. The terms “first,” “second,” third” may be used to describe various elements but the elements are not limited by the terms and a “first element” may be referred to as a “second element”.

Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment.

As used herein, each of the terms “Ar”, “Fe”, “N₂”, and the like may refer to a material made of elements included in each of the terms and is not a chemical formula representing a stoichiometric relationship.

The embodiments herein may be described and illustrated in terms of blocks, as shown in the drawings, which carry out a described function or functions. These blocks, which may be referred to herein as units or modules or the like, or by names such as device, logic, circuit, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, and the like, and may also be implemented by or driven by software and/or firmware (configured to perform the functions or operations described herein).

Hereinafter, various embodiments of the present disclosure are described with reference to the accompanying drawings.

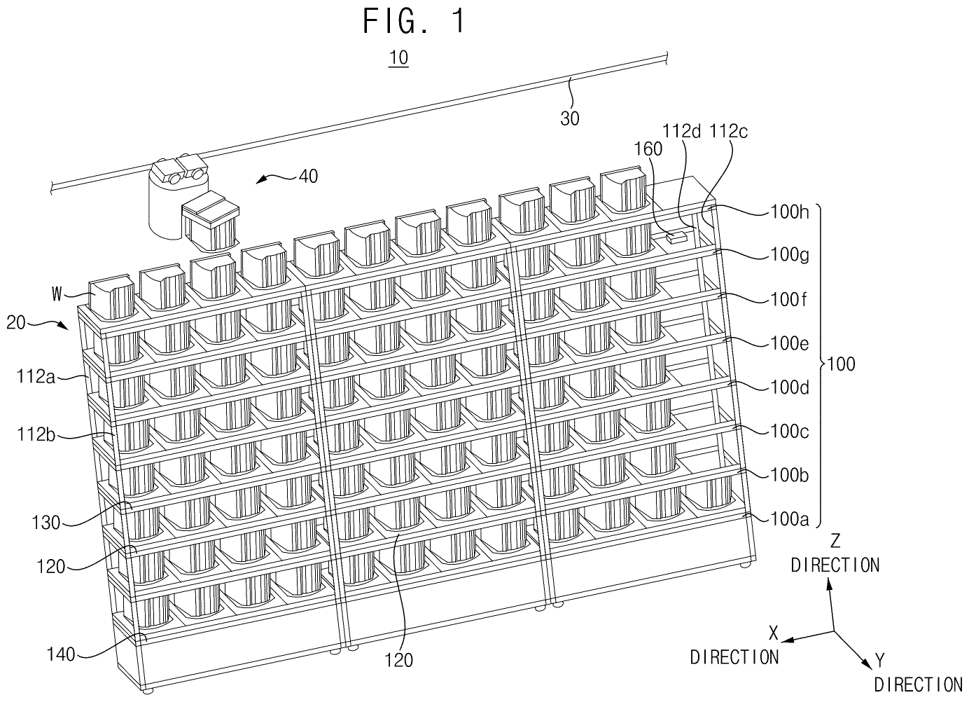

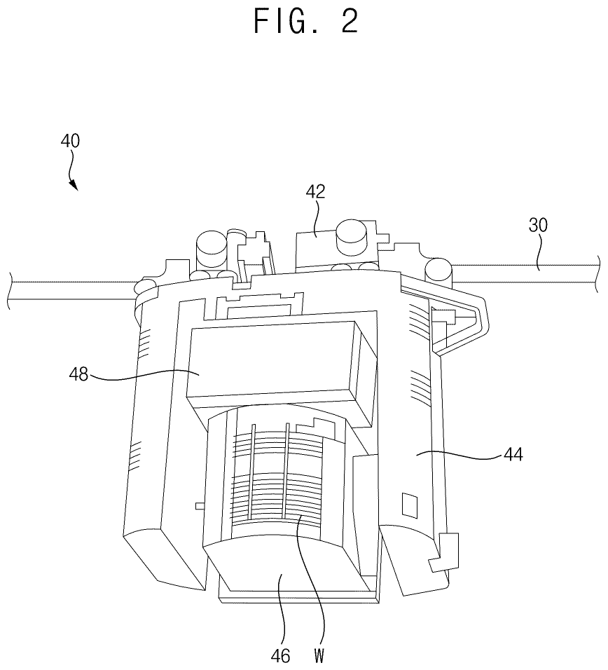

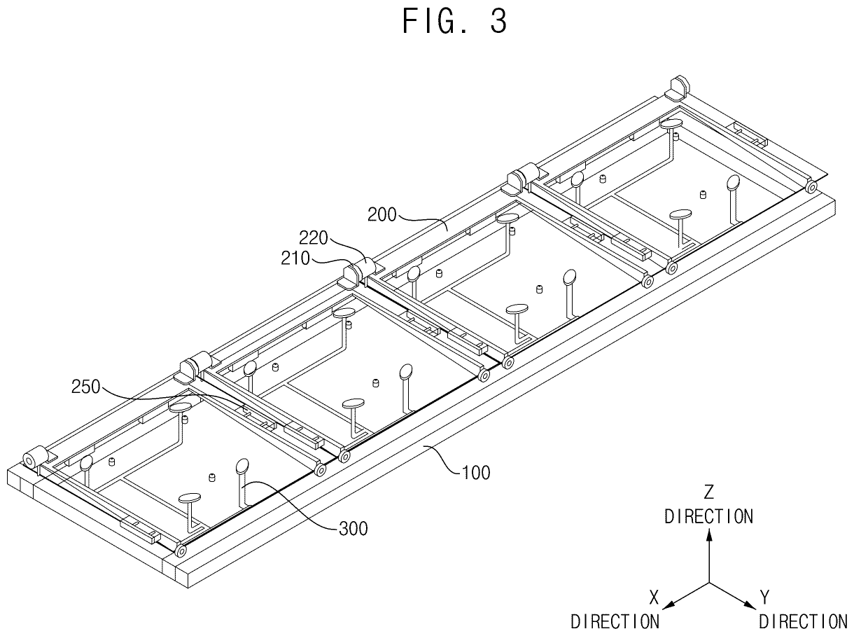

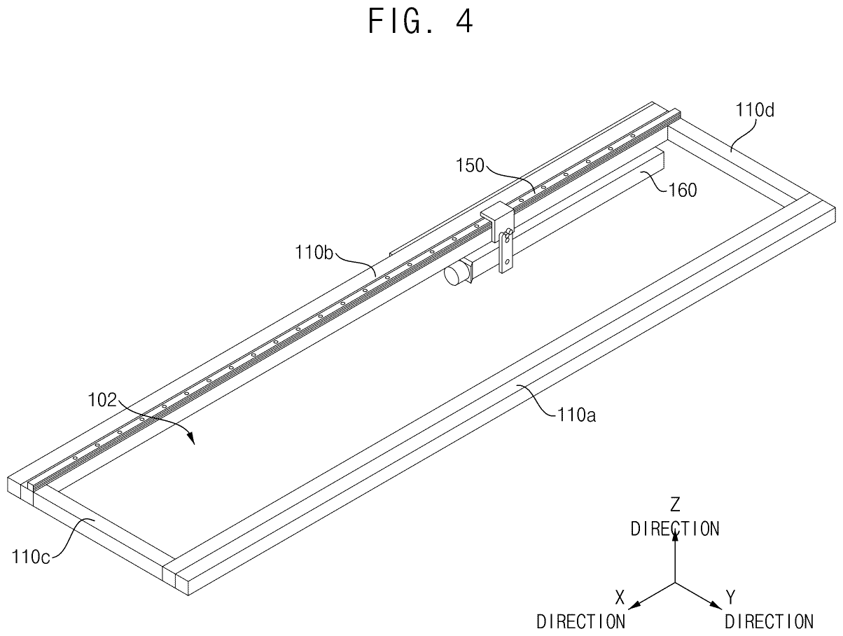

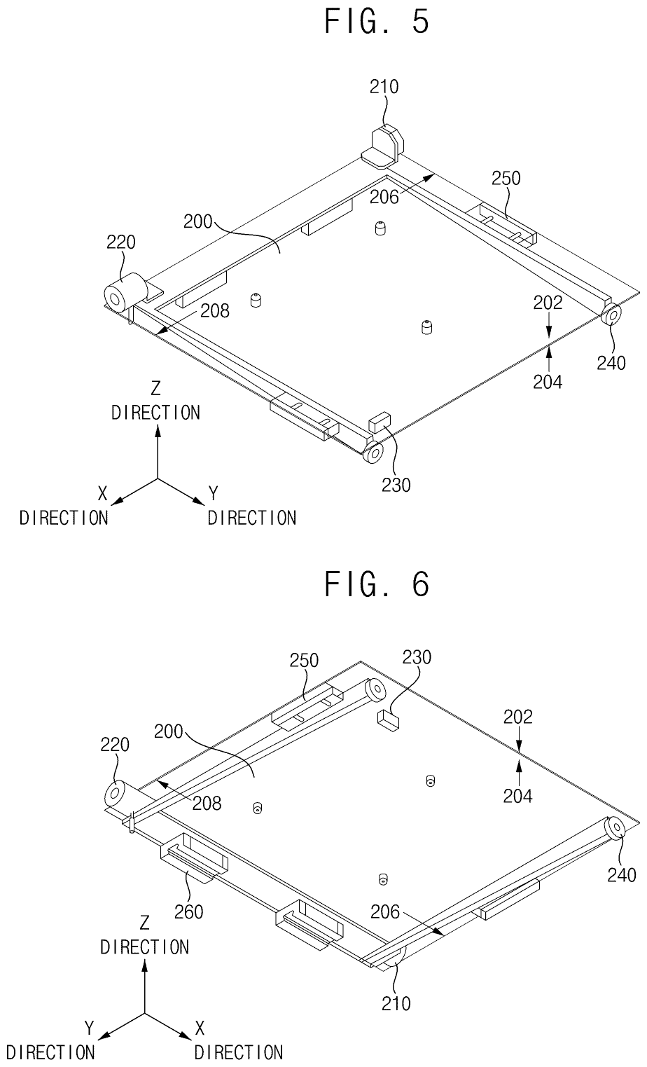

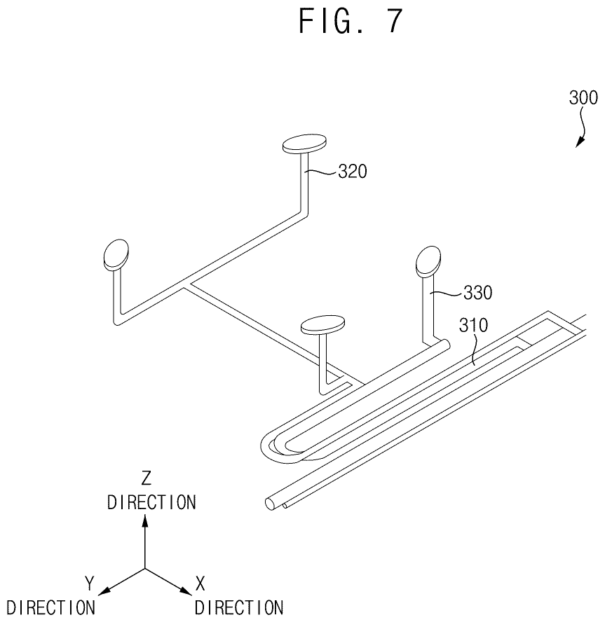

FIG. 1 is a perspective view illustrating a storage system for semiconductor devices, according to an embodiment. FIG. 2 is a perspective view illustrating a driving rail and a transport device in FIG. 1, according to an embodiment. FIG. 3 is a perspective view illustrating a plurality of shelves provided on a frame in FIG. 1, according to an embodiment. FIG. 4 is a perspective view illustrating the frame in FIG. 3, according to an embodiment. FIGS. 5 and 6 are perspective views illustrating one of the plurality of shelves in FIG. 3, according to an embodiment. FIG. 7 is a perspective view illustrating a gas supply portion in FIG. 3, according to an embodiment.

Referring to FIGS. 1 to 7, a storage system 10 for semiconductor devices may include a storage apparatus 20 configured to accommodate a plurality of semiconductor devices W, at least one driving rail 30 provided on the storage apparatus 20, and a transport device 40 configured to carry the plurality of semiconductor devices W on the driving rail 30.

In a semiconductor manufacturing process, the plurality of semiconductor devices W may be manufactured using a plurality of semiconductor process equipment. The semiconductor processing equipment may perform manufacturing processes at different stages for each semiconductor device of the plurality of semiconductor devices W. Alternatively or additionally, the semiconductor device W processed in one of the plurality of semiconductor process equipment may be automatically transported to the next process equipment by the transport device 40. For example, the semiconductor device W may include a semiconductor wafer and/or a semiconductor reticle.

In example embodiments, the storage system 10 may be referred to as a system capable of storing the plurality of semiconductor devices W in the semiconductor manufacturing process. When storage of the plurality of semiconductor devices W is needed in the semiconductor manufacturing process, the storage system 10 may temporarily store the plurality of semiconductor devices W among the semiconductor processing equipment. For example, when the plurality of semiconductor process equipment are operated in combination and/or simultaneously, the storage system 10 may temporarily store the plurality of semiconductor devices W. As another example, when the semiconductor processing equipment is in a working state, the storage system 10 may temporarily store the plurality of semiconductor devices W.

In example embodiments, the driving rail 30 may include at least one of a straight driving rail and a curved driving rail extending in parallel. The driving rail 30 may be provided along a ceiling of a semiconductor manufacturing line where the plurality of semiconductor process equipment are continuously disposed. For example, the driving rail 30 may include a pair of rails extending parallel to each other.

The storage apparatus 20 may be provided under the straight driving rail of the driving rail 30. As used herein, a direction (e.g., X direction) in which the straight driving rail of the driving rail 30 extends may be referred to as a first horizontal direction, and/or a horizontal direction (e.g., Y direction) orthogonal to the first horizontal direction may be referred to as a second horizontal direction. Alternatively or additionally, a direction (e.g., Z direction) orthogonal to the first horizontal direction and the second horizontal direction may be referred to as a vertical direction.

As shown in FIG. 2, the transport device 40 may include a driving portion 42 configured to move the transport device 40 along the driving rail 30 that may be provided above the semiconductor manufacturing line. The transport device 40 may further include an accommodating portion 44 supported by the driving portion 42 at a lower portion of the driving rail 30, and configured to accommodate at least one semiconductor device of the plurality of the semiconductor devices W. For example, the transport device 40 may load and/or unload the plurality of semiconductor devices W from the storage apparatus 20. The transport device 40 may further include a carrier 46 configured to store the at least one semiconductor device W, and a loading portion 48 configured to move the carrier 46 up and down in order to mount and/or remove the at least one semiconductor device W from the accommodating portion 44.

In an embodiment, the transport device 40 may transport the carrier 46, on which the plurality of semiconductor devices W are accommodated, to the storage apparatus 20. The transport device 40 may move using the driving portion 42 along a movement path on which the driving rail 30 is installed. The driving portion 42 may move along the driving rail 30 installed along the movement path, and may deliver the at least one semiconductor device W to the process equipment and/or the storage apparatus 20.

As used herein, the transport device 40 may be referred to as an overhead hoist transport (OHT). In an embodiment, the transport device 40 may lower the at least one semiconductor device W from upper portions of the process equipment and/or the storage apparatus 20. For example, the transport device 40 may be and/or may include an automated guided vehicle (AGV) that may move between the process equipment and the storage apparatus 20 in the form of a vehicle. Alternatively or additionally, the transport device 40 may be and/or may include a rail guided vehicle (RGV) that may move along a path provided between the process equipment and the storage apparatus 20.

In example embodiments, the storage apparatus 20 may receive and/or store the at least one semiconductor device W from the transport device 40. For example, the storage apparatus 20 may receive the at least one semiconductor device W from the transport device 40 in the vertical direction (e.g., Z direction) from the upper portion of the storage apparatus 20. That is, the storage apparatus 20 may receive the carrier 46 in which the at least one semiconductor device W is accommodated from the accommodating portion 44 of the transport device 40.

The storage apparatus 20 may include a plurality of frames 100 (e.g., first frame 100a, second frame 100b, third frame 100c, fourth frame 100d, fifth frame 100e, sixth frame 100f, seventh frame 100g, and eighth frame 100h, hereinafter referred to generally as “100”) that may be stacked on one another in the vertical direction (e.g., Z direction). For example, the plurality of frames may be stacked at least partially on top of one another in the vertical direction. The storage apparatus 20 may further include a plurality of driving portions 160 that may be provided on the plurality of frames 100, and a plurality of shelves 200 that may be provided on the plurality of frames 100. The storage apparatus 20 may further include a coupling portion having first couplers 210 and second couplers 220 that may be engaged and/or separated from each other. The storage apparatus 20 may further include a sensor 230 that may be configured to determine whether another shelf is vertically disposed, and elastic members 250 that may be configured to prevent collision with other shelves. The storage apparatus 20 may further include a gas supply portion 300 connected (e.g., coupled) to the plurality of shelves 200 to supply a purge gas to the plurality of semiconductor devices W.

In example embodiments, the frame 100 may include a first horizontal rod 110a and a second horizontal rod 110b that may extend parallel to each other in the first horizontal direction (e.g., X direction). Alternatively or additionally, the frame 100 may include a third horizontal rod 110c and a fourth horizontal rod 110d that may extend in the second horizontal direction (e.g., Y direction) to connect the first and second horizontal rods 110a and 110b to each other. The frame 100 may further include a plurality of vertical rods 112 extending parallel to each other in the vertical direction (e.g., Z direction) at positions where the first to fourth horizontal rods 110a to 110d may be connected to each other.

As shown in FIGS. 3 and 4, the frame 100 may include an opening 102 that may be defined by the first to fourth horizontal rods 110a to 110d. The transport device 40 may pass through the frame 100 through the opening 102 of the frame 100, and may move in the vertical direction (e.g., Z direction). Alternatively or additionally, the transport device 40 may move between the plurality of frames 100, that may be provided on different floors, through the opening 102.

For example, each frame of the plurality of frames 100 may have an upper open portion and a lower open portion opposite to each other. The frame 100 may be and/or may include a box shape that may have an overall rectangular parallelepiped shape with an open top surface, an open bottom surface, and open side surfaces. The frame 100 may accommodate at least a portion of the plurality of semiconductor devices W in an internal space.

The plurality of frames 100 may be stacked on each other in the vertical direction (e.g., Z direction). For example, the plurality of frames may be stacked at least partially on top of one another in the vertical direction. Alternatively or additionally, the plurality of frames 100 may be sequentially stacked (e.g., first to eighth frames 100a to 100h. In an embodiment, the plurality of frames 100 may be fixed through vertical rods (e.g., first vertical rod 112a, second vertical rod 112b, third vertical rod 112c, and fourth vertical rod 112d).

As shown in FIG. 1, the storage apparatus 20 may eight (8) stacked frames 100 (e.g., first to eighth frames 100a to 100h). However, the present disclosure is not limited thereto, and for example, the storage apparatus 20 may include less frames (e.g., less than eight (8)) and/or may include more frames (e.g., more than eight (8), such as, 20, for example).

The frame 100 may include at least one guide rail 150 extending in the first horizontal direction (e.g., X direction). The guide rail 150 may guide the shelf 200 on the frame 100. The guide rail 150 may be provided on the first horizontal rod 110a and/or the second horizontal rod 110b. The guide rail 150 may restrict movement of the shelf 200 on the frame 100. When the guide rail 150 restricts the movement of the shelf 200, the shelf 200 may stably reciprocate on the frame 100 in the first horizontal direction (e.g., X direction).

In example embodiments, the driving portion 160 may slide the plurality of shelves 200 on the guide rail 150. The driving portion 160 may reciprocate along the guide rail 150 in the first horizontal direction (e.g., X direction). The driving portion 160 may move along the guide rail 150 by gripping and/or fixing at least one of the plurality of shelves 200. When the drive portion 160 grips and/or fixes at least one of the plurality of shelves 200, other shelves engaged with the gripped shelf may move together with the gripped shelf.

The driving portion 160 may move at a predetermined speed on the frame 100. When the driving portion 160 moves on the frame 100, the predetermined speed may increase and/or decrease. For example, when the driving portion 160 starts moving on the frame 100, the predetermined speed may be gradually increased. That is, the driving portion 160 may gradually increase the speed of the driving portion 160 until the driving portion 160 reaches a speed substantially similar and/or the same as the predetermined speed. Alternatively or additionally, when the driving portion 160 stops moving on the frame 100, the predetermined speed may be gradually decreased. That is, the driving portion 160 may gradually decrease the speed of the driving portion 160 until the driving portion 160 stops and/or reaches a rest speed.

The frames 100 may include a lower frame 120 and an upper frame 130 stacked on the lower frame 120. Selected shelves disposed on the upper frame 130 and/or the lower frame 120 in the vertical direction (e.g., Z direction) may slide together in the first horizontal direction (e.g., X direction) by the driving portion 160. For example, the shelves 200 provided on the sixth frame 100f may slidably move together with the shelves 200 that are provided on the seventh and eighth frames 100g and 100h in the first horizontal direction (e.g., X direction).

The frames 100 may include a lowermost frame 140 that may be positioned at a lowermost portion among the stacked frames 100. The shelves 200 disposed on the lowermost frame 140 may be fixed so as not to move (e.g., prevent movement) in the first horizontal direction (e.g., X direction).

In an embodiment, the first to fourth horizontal rods 110a to 110d and the vertical rods 112 may be composed of and/or may include a same material. For example, the first to fourth horizontal rods 110a to 110d and the vertical rods 112 may include a metal material such as, but not limited to, iron (Fe), stainless steel, and the like. Alternatively or additionally, the first to fourth horizontal rods 110a to 110d and the vertical rods 112 may include a plastic material.

The frames 100 may include a metal material and/or a plastic material having a relatively strong hardness and/or a relatively high toughness. For example, when the carrier 46 storing the at least one semiconductor device W is accommodated in the frame 100, the plurality of frames 100 may protect the carrier 46 and the at least one semiconductor device W accommodated therein from external impact. In an embodiment, the plurality of frames 100 may be individually stored and/or managed. In an optional or additional embodiment, when the frame 100 includes a rectangular parallelepiped structure, the plurality of frames 100 may be stored in a stacked state.

In example embodiments, the plurality of shelves 200 may be provided on a plurality of frames 100. The plurality of shelves 200 may be provided to be movable in the first horizontal direction (e.g., X direction) on the frame 100.

As shown in FIGS. 5 and 6, the shelf 200 may have an upper surface 202 and a lower surface 204 that may be opposite to the upper surface 202. The shelf 200 may have a first side surface 206 and a second side surface 208 that may be opposite to the first side surface 206. The first side surface 206 and the second side surface 208 may face the first horizontal direction (e.g., X direction). Each shelf of the plurality of shelves 200 may accommodate at least one semiconductor device W on the upper surface 202 of the shelf. Alternatively or additionally, each shelf of the plurality of shelves 200 may accommodate a carrier 46, on which the at least one semiconductor device W is accommodated, on the upper surface 202 of the shelf.

The shelf 200 may include a wheel 240 that may rotate on the frame 100, and a trench 260 that may restrict the movement of the shelf 200 through the guide rail 150.

In an embodiment, the plurality of shelves 200 may slide along the guide rail 150. For example, the plurality of shelves 200 may slidably move on the guide rail 150 through the drive portion 160 of the frame 100. Alternatively or additionally, the plurality of shelves 200 engaged to each other may move together in the first horizontal direction (e.g., X direction) on the guide rail 150.

The wheel 240 may rotate on the frame 100 to stably move the shelf 200 on the frame 100. In an embodiment, the wheel 240 may include a tire. The tire may smoothly move the shelf 200 on the frame 100 through frictional force with the frame 100.

The trench 260 may surround the guide rail 150 of the frame 100. When the trench 260 surrounds the guide rail 150, the movement of the shelf 200 may be restricted to the first horizontal direction (e.g., X direction). When the shelf 200 rotates, the trench 260 may contact the guide rail 150 to limit rotation of the shelf 200.

The shelf 200 may move at the predetermined speed by the drive portion 160. For example, when the shelf 200 starts moving on the frame 100, the speed of the shelf 200 may be gradually increased until the predetermined speed is reached. Alternatively or additionally, when the shelf 200 stops moving on the frame 100, the speed of the shelf 200 may gradually decrease until the shelf 200 comes to a stop.

When the shelf 200 moves at the predetermined speed that may gradually increase and/or decrease, abrasion occurring on the tire of the wheel 240 and/or from the trench 260 may be reduced. As a result, generation of contaminant particles may be reduced and/or prevented in the semiconductor manufacturing process.

The number of shelves 200 disposed on the lowermost frame 140 may be a first number. The number of the shelves 200 disposed on the frames 100 stacked on the lowermost frame 140 may be a second number. The second number may be smaller than the first number.

When the first number of shelves 200 disposed on the lowermost frame 140 is greater than the second number of shelves 200 stacked on the lowermost frame 140, the shelf 200 may secure a movable space on the frame 100. That is, when the first number of shelves 200 disposed on the lowermost frame 140 is greater than the second number of shelves 200 stacked on the lowermost frame 140, the storage apparatus 20 may maximize storage capacity of the plurality of semiconductor devices W. For example, the first number of shelves 200 disposed on the lowermost frame 140 may be between four (4) and twenty (20).

In example embodiments, the first and second couplers 210 and 220 may be provided at positions corresponding to each other on the first and second side surfaces 206 and 208. In an embodiment, the first coupler 210 may include a permanent magnet.

Alternatively or additionally, the second coupler 220 may include an electromagnet.

In an embodiment, the permanent magnet and the electromagnet may be engaged and/or separated (e.g., disengaged) from each other through magnetic force. For example, when a current is supplied to the electromagnet, the electromagnet may be engaged with the permanent magnet. Alternatively or additionally, when the current is blocked from (and/or not supplied to) the electromagnet, the electromagnet may be separated from the permanent magnet.

The shelves 200 selected from among the plurality of shelves 200 and that are disposed adjacent to each other may be engaged to each other through the first and second couplers 210 and 220. The shelves 200 engaged to each other through the first and second couplers 210 and 220 may slide together in the first horizontal direction (e.g., X direction). When the engaged shelves (the selected shelves) 200 slidably move together in the first horizontal direction (e.g., X direction), the engaged shelves 200 may move apart from a vertical movement path of the transport device 40. That is, the transport device 40 may move in the vertical direction (e.g., Z direction) inside the frames 100 through the openings 102 of the frames 100.

In example embodiments, the sensor 230 may detect another shelf located in the vertical direction (e.g., Z direction) through radio waves. The sensor 230 may be provided on the upper surface 202 of the shelf 200 to generate the radio waves. The sensor 230 may obtain a reflected radio wave generated when the radio wave collides with the lower surface 204 of another shelf. The sensor 230 may determine whether or not the other shelf is disposed in the vertical direction (e.g., Z direction) through the reflected radio wave.

The sensor 230 may be and/or may include a non-contact sensor. The non-contact sensor may include, but not be limited to, a radio detection and ranging (RADAR) sensor, a light detection and ranging (LIDAR) sensor, a vision sensor, an infrared sensor, an ultrasonic sensor, and the like.

In example embodiments, the elastic members 250 may be provided on the first and second side surfaces 206 and 208, respectively. The elastic members 250 may include an elastic material. For example, the elastic material may include, but not be limited to, rubber. Alternatively or additionally, the elastic members 250 may be and/or may include springs.

In an embodiment, the elastic members 250 may be provided to be staggered from each other on the first and second side surfaces 206 and 208. When the elastic members 250 are provided to be staggered from each other on the first and second side surfaces 206 and 208, the elastic members 250 may absorb an impact between the shelves 200 over a relatively wide area. Alternatively or additionally, the elastic members 250 may be provided to correspond to each other. When the elastic members 250 are provided to correspond to each other on the first and second side surfaces 206 and 208, the elastic members 250 may concentrate the impact between the shelves on the elastic members 250.

In example embodiments, the gas supply portion 300 may include a plurality of gas supply pipes 310 configured to supply the purge gas to the plurality of semiconductor devices W. The gas supply pipes 310 may be respectively connected to the shelves 200.

For example, the gas supply pipe 310 may supply the purge gas to the at least one semiconductor device W that may be accommodated on the shelf 200. Alternatively or additionally, the gas supply pipe 310 may supply the purge gas into the carrier 46 accommodated on the shelf 200. The purge gas may include a material capable of maintaining a state of the semiconductor device W. For example, the purge gas may include, but not be limited to, nitrogen (N₂), argon (Ar), and the like.

As shown in FIG. 7, the gas supply pipe 310 may include an inlet 320 for supplying the purge gas onto the shelf 200, and an outlet 330 for recovering the purge gas. The purge gas supplied from the inlet 320 may be used to maintain the state of the at least one semiconductor device W. Alternatively or additionally, the used purge gas may be discharged through the outlet 330.

The gas supply pipe 310 may include a flexible pipe capable of supplying the purge gas when the shelf 200 slides on the frame 100. When the shelf 200 slides on the frame 100, the flexible pipe may be bent according to a location of the shelf 200. When the flexible pipe is bent, the flexible pipe may supply the purge gas regardless of the position of the shelf 200.

As described above, the plurality of shelves 200 of the storage apparatus 20 may move in the first horizontal direction (e.g., X direction) along the guide rail 150 through the drive portion 160 on the plurality of frames 100. Among the plurality of shelves 200, the engaged shelves (the selected shelves) may move together in the first horizontal direction (e.g., X direction). When the engaged shelves move together in the horizontal direction (e.g., X direction) and the plurality of frames 100 have openings 102 exposed upward, the storage apparatus 20 may expose the semiconductor device W to be transported in the vertical direction (e.g., Z direction). The shelves 200 may not interfere with the movement path of the transport device 40, and the transport device 40 may pass through the plurality of frames 100. As a result, the storage apparatus 20 may not need space and/or additional devices for exposing the semiconductor device W, and as such, space utilization of the storage apparatus may be improved, when compared to related storage apparatuses.

In addition, the storage apparatus 20 may not have a need for a crane structure for exposing the semiconductor devices W to the transport device 40. When the storage apparatus 20 does not have the crane structure, safety accidents that may occur in a process of installing the crane structure may be reduced and/or prevented.

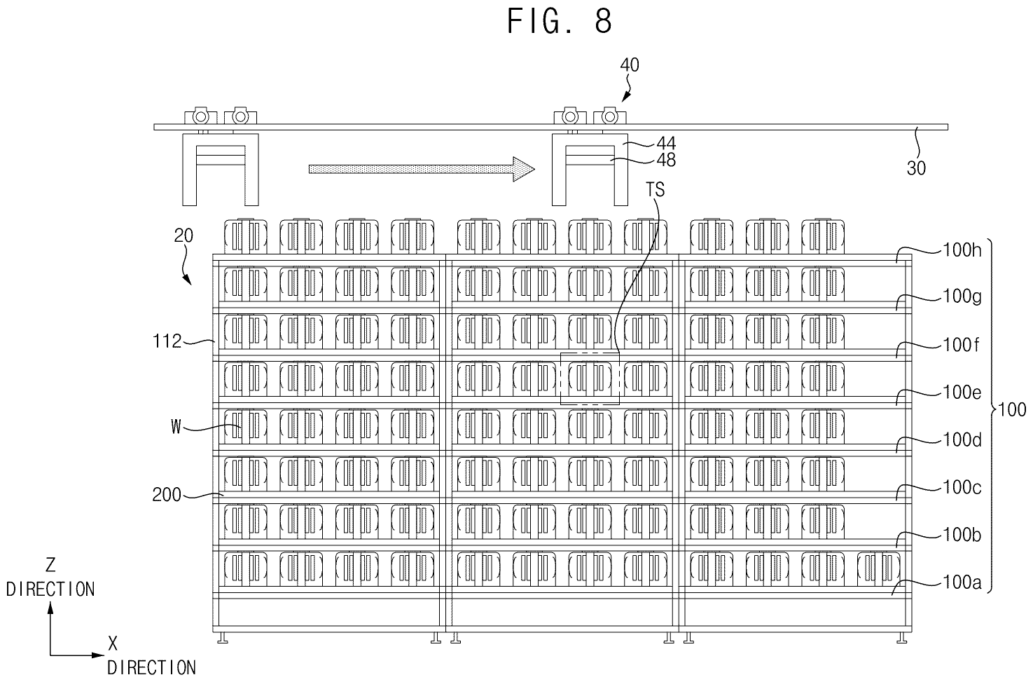

Hereinafter, a method of storing semiconductor devices using the storage system in FIG. 1 is described with reference to FIGS. 8 to 12.

FIGS. 8 to 12 are views illustrating a process of unloading a semiconductor device from a storage system, according to an embodiment.

Referring to FIGS. 8 to 12, a transport device 40 may move above a target semiconductor device TW stored on a storage apparatus 20 for semiconductor devices. The transport device 40 may be aligned in a vertical direction (e.g., Z direction) on top of the target semiconductor device TW.

In example embodiments, a plurality of semiconductor devices W may be accommodated on a plurality of shelves 200 that may be slidably movable on a plurality of frames 100. The semiconductor devices W may include the target semiconductor device TW. The target semiconductor device TW may be referred to as a semiconductor device to be moved between semiconductor process equipment. The target semiconductor device TW may move to a next semiconductor process through the transport device 40.

As shown in FIG. 8, the transport device 40 may move along a driving rail 30 on the storage apparatus 20 in a first horizontal direction (e.g., X direction). The transport device 40 may stop at the top of the target semiconductor device TW.

The plurality of shelves 200 may move in the first horizontal direction (e.g., X direction) on the frames 100. For example, the plurality of shelves 200 may move in the first horizontal direction (e.g., X direction) in order to expose (e.g., make accessible) the target semiconductor device TW to the transport device 40.

In example embodiments, the plurality of shelves 200 may be arranged on the frames 100 in a first arrangement. The plurality of shelves 200 may move moving target shelves SS1 from the first arrangement in order to expose the target semiconductor device TW to the transport device 40, and as such, allow the transport device 40 to obtain the target semiconductor device TW from the storage apparatus 20.

The moving target shelves SS1 from among the plurality of shelves 200 may be engaged to each other. For example, the moving target shelves SS1 may be engaged to each other through the first and second couplers 210 and 220. That is, the moving target shelves SS1 may be engaged to each other through magnetic force (e.g., permanent magnets and electromagnets). The moving target shelves SS1 may move along the frames 100 in the first horizontal direction (e.g., X direction). The moving target shelves SS1 may be referred to as shelves that are located on the target semiconductor device TW.

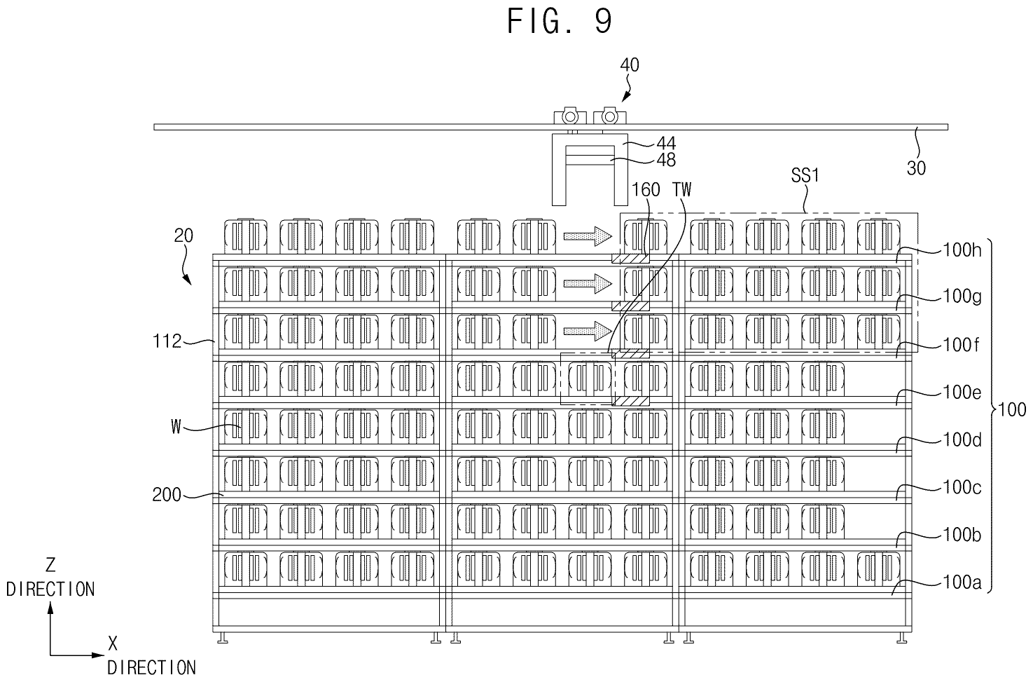

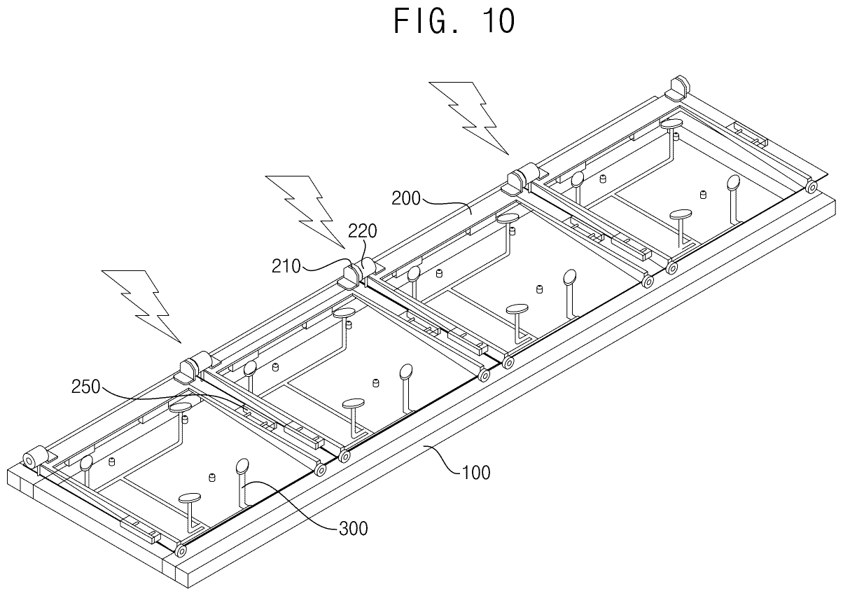

As shown in FIGS. 9 and 10, the frames 100 may have first to eighth frames 100a to 100h that may be sequentially stacked. The plurality of shelves 200 may be provided on the first to eighth frames 100a to 100h, respectively. Among the plurality of shelves 200, the moving target shelves SS1 may move together. When the moving target shelves SS1 move together, the target semiconductor device TW may be exposed to the transport device 40.

For example, among the shelves 200 disposed on the sixth to eighth frames 100f to 100h, the moving target shelves SS1 may move together in the first horizontal direction (e.g., X direction). For example, the moving target shelves SS1 disposed on the sixth frame 100f may be engaged to each other through the magnetic force (e.g., first and second couplers 210 and 220). As another example, the moving target shelves SS1 disposed on the seventh frame 100g may be engaged to each other through the magnetic force (e.g., first and second couplers 210 and 220). The moving target shelves SS1 disposed on the eighth frame 100h may be engaged to each other through the magnetic force (e.g., first and second couplers 210 and 220). When the moving target shelves SS1 disposed on the sixth to eighth frames 100f to 100h move together in the first horizontal direction (e.g., X direction), the target semiconductor device TW may be exposed to the transport device 40.

In an embodiment, when the transport device 40 transports the target semiconductor device TW to a next semiconductor process, the moving target shelves SS1 may return to the first arrangement.

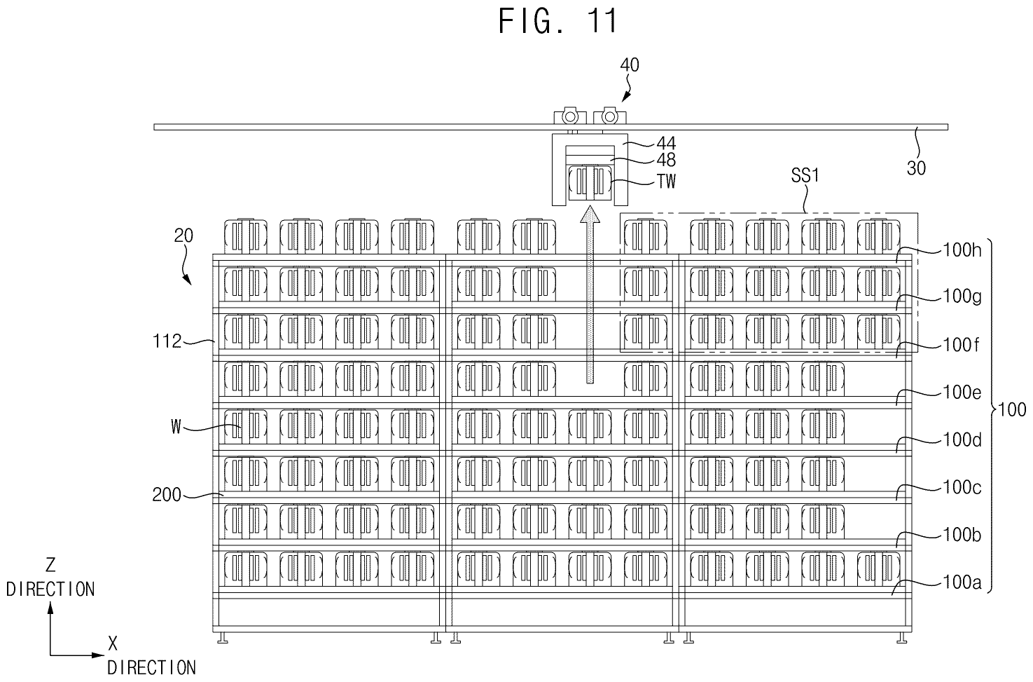

As shown in FIG. 11, the shelf 200 accommodating the target semiconductor device TW may determine whether other shelves are arranged in the vertical direction (e.g., Z direction) through a sensor 230. When it is determined that the other shelves are not arranged on the target semiconductor device TW, a loading portion 48 of the transport device 40 may descend in the vertical direction (e.g., Z direction).

The transport device 40 may lower the loading portion 48 in the vertical direction (e.g., Z direction) to fix (e.g., grip) the target semiconductor device TW. The loading portion 48 may descend in the vertical direction (e.g., Z direction) and be fixed to the target semiconductor device TW. Alternatively or additionally, the loading portion 48 may rise (e.g., move upwards) in the vertical direction (e.g., Z direction) to accommodate the target semiconductor device TW in an accommodating portion 44 of the transport device 40. The loading portion 48 may fix and transport the carrier 46 accommodating the target semiconductor device TW.

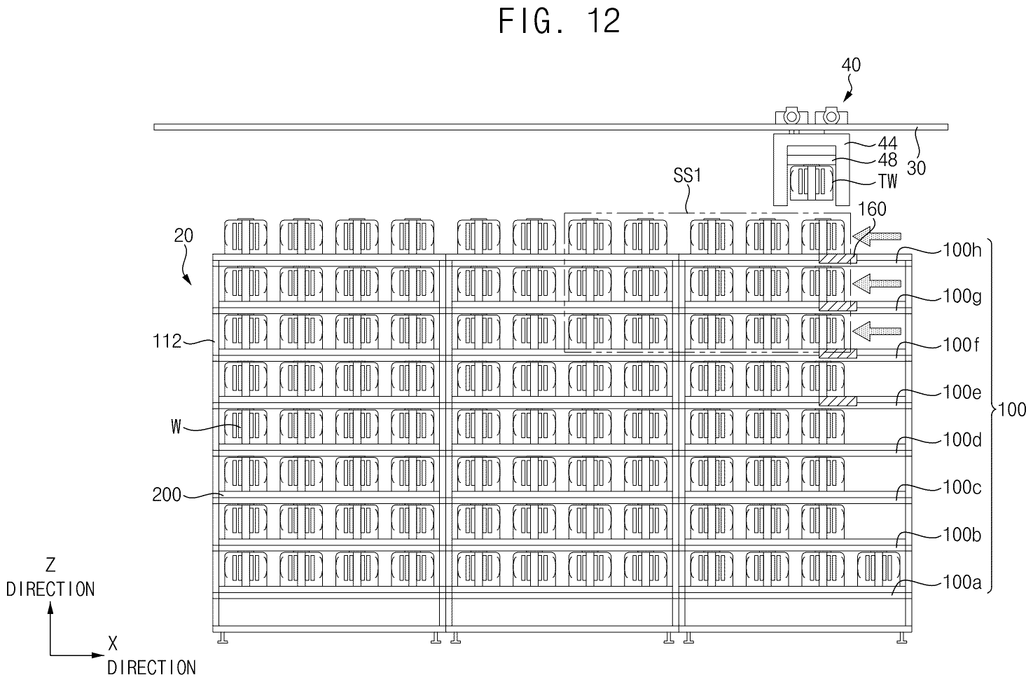

As shown in FIG. 12, when the target semiconductor device TW is transported to the next semiconductor process through the transport device 40, the moving target shelves SS1 may return to the first arrangement.

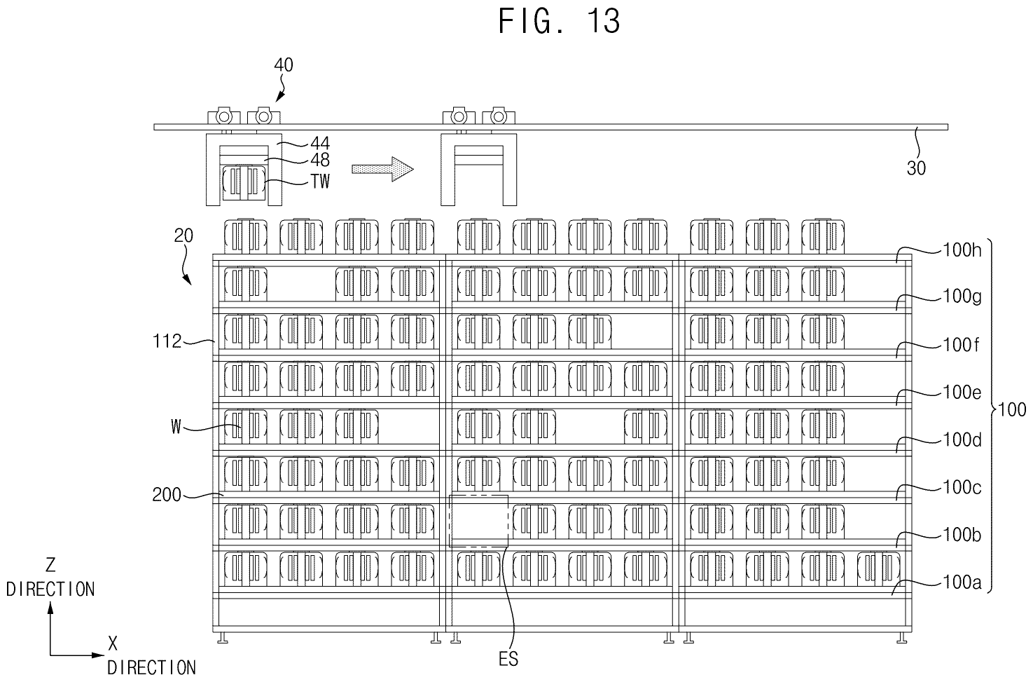

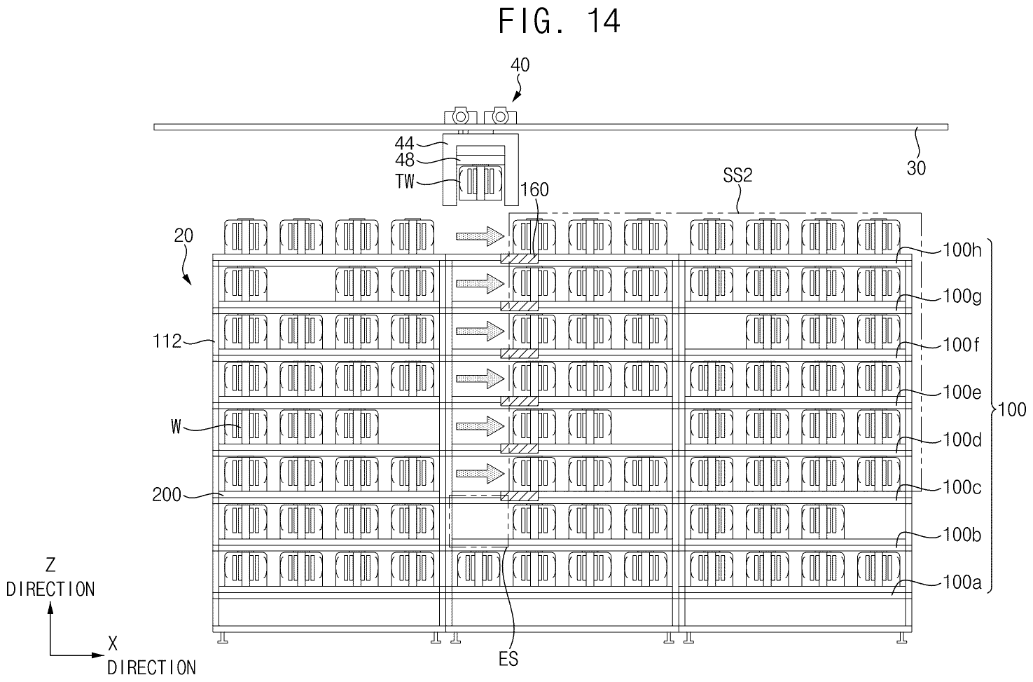

FIGS. 13 to 16 are views illustrating a process of loading a semiconductor device onto a storage system, according to an embodiment.

Referring to FIGS. 13 to 16, the transport device 40 holding and/or fixing the target semiconductor device TW may move to a top of (e.g., position above) an empty shelf ES on the storage apparatus 20. That is, the transport device 40 may be aligned in the vertical direction (e.g., Z direction) above the empty shelf ES.

In example embodiments, the target semiconductor device TW may be referred to as a semiconductor device to be moved between the semiconductor process equipment. The target semiconductor device TW may be stored in the storage apparatus 20 through the transport device 40.

As shown in FIG. 13, the transport device 40 may move along the driving rail 30 on the storage apparatus 20 in the first horizontal direction (e.g., X direction). The transport device 40 may stop at the top of the empty shelf ES.

The plurality of shelves 200 may move in the first horizontal direction (e.g., X direction) on the frames 100. For example, the plurality of shelves 200 may expose the empty shelf ES to the transport device 40.

In example embodiments, the plurality of shelves 200 may be arranged on the frames 100 in a second arrangement. The plurality of shelves 200 may move the moving target shelves SS2 from the second arrangement in order to expose (e.g., make accessible) an upper surface of the empty shelf ES to the transport device 40.

The moving target shelves SS2, from among the plurality of shelves 200, may be engaged to each other. For example, the moving target shelves SS2 may be engaged to each other through the first and second couplers 210 and 220. That is, the moving target shelves SS2 may be engaged to each other through a magnetic force (e.g., permanent magnets and electromagnets). The moving target shelves SS2 may move along the frames 100 in the first horizontal direction (e.g., X direction). The moving target shelves SS2 may be referred to as shelves located on the target semiconductor device TW.

As shown in FIG. 14, among the shelves 200 disposed on the third to eighth frames 100c to 100h, the moving target shelves SS2 may move together in the first horizontal direction (e.g., X direction). The moving target shelves SS2 on the third to eighth frames 100c to 100h may move together in the first horizontal direction (e.g., X direction), and the empty shelf ES may be exposed to the transport device 40.

In an embodiment, the transport device 40 may place the target semiconductor device TW on the empty shelf ES that may have been exposed to the transport device 40. Alternatively or additionally, the moving target shelves SS2 may return to the second arrangement after the transport device has placed the target semiconductor device TW on the empty shelf ES.

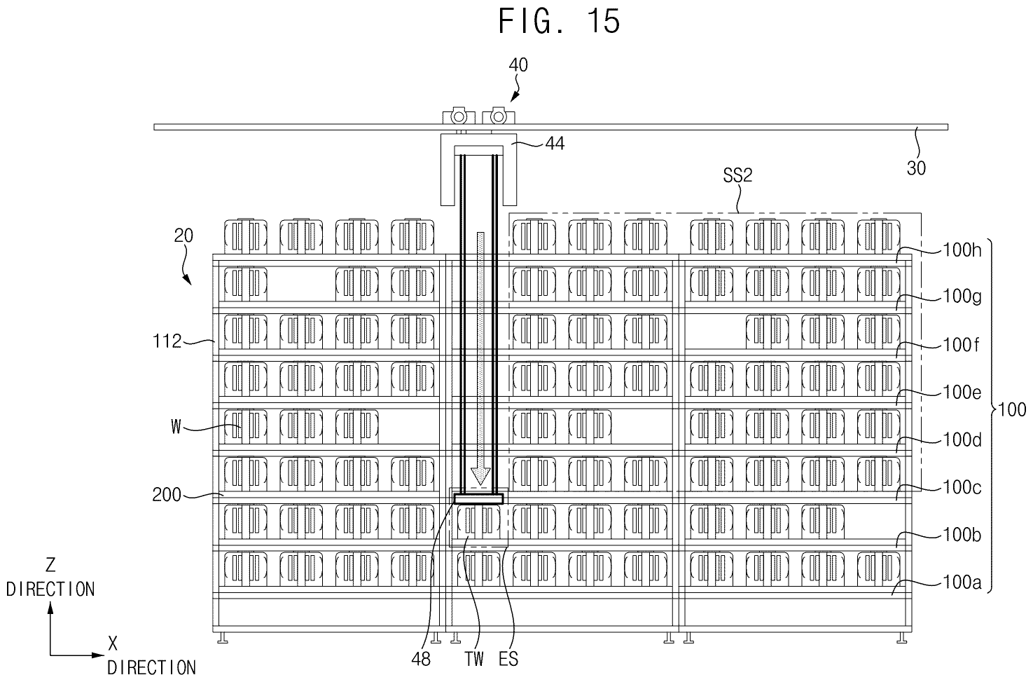

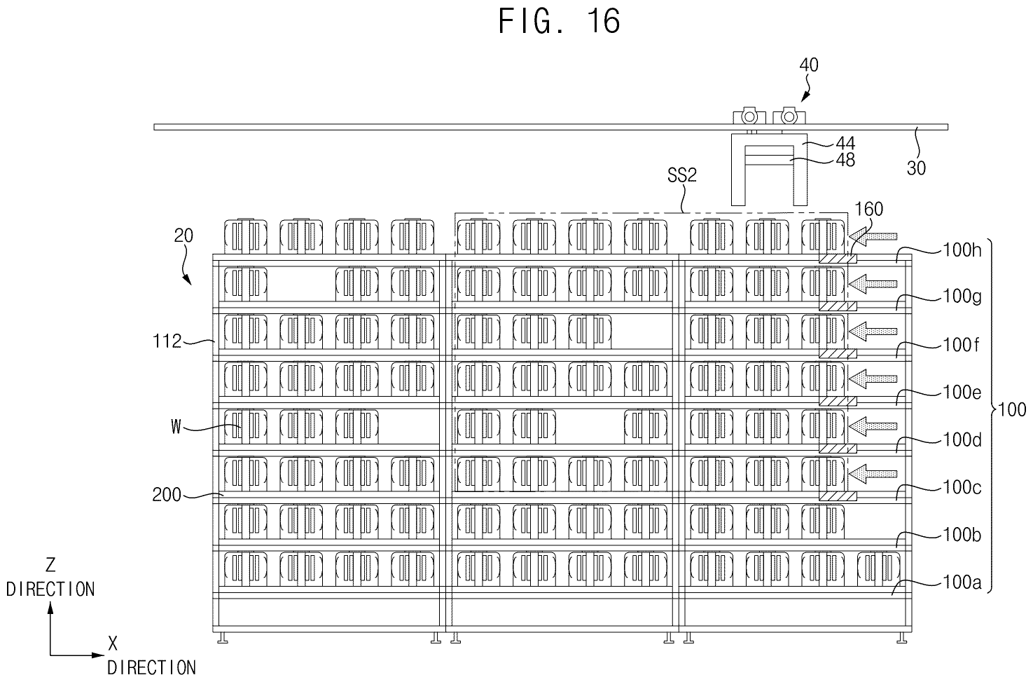

As shown in FIG. 15, the transport device 40 may lower (e.g., move downwards) the loading portion 48 holding and fixing the target semiconductor device TW in the vertical direction (e.g., Z direction). The loading portion 48 may place the target semiconductor device TW on the empty shelf ES. After the loading portion 48 places the target semiconductor device TW on the empty shelf ES, the loading portion 48 may rise (e.g., move upwards) in the vertical direction (e.g., Z direction). The loading portion 48 may accommodate the carrier 46 accommodating the target semiconductor device TW on the empty shelf ES.

As shown in FIG. 16, when the target semiconductor device TW is accommodated on the empty shelf ES through the transport device 40, the moving target shelves SS2 may return to the second arrangement.

The foregoing is illustrative of example embodiments and is not to be construed as limiting thereof. Although a few example embodiments have been described, those skilled in the art may readily appreciate that many modifications may be possible in example embodiments without materially departing from the novel teachings and advantages of the present invention. Accordingly, such modifications may be intended to be included within the scope of example embodiments as defined in the claims.

What is claimed is:

1. A storage apparatus for a plurality of semiconductor devices, comprising:
a plurality of frames stacked at least partially on top of one another in a vertical direction, each frame of the plurality of frames comprising at least one guide rail extending in a first horizontal direction;
a plurality of shelves provided to be slidably movable on the plurality of frames along the at least one guide rail, each shelf of the plurality of shelves configured to accommodate a portion of the plurality of semiconductor devices on an upper surface of the shelf;
a coupling portion comprising first couplers and second couplers that are selectively engaged with each other by an external control signal, the first couplers provided on a first side surface of each shelf of the plurality of shelves, the second couplers provided on a second side surface of each shelf of the plurality of shelves, the second side surface being opposite to the first side surface, the first side surface and the second side surface extending along a second horizontal direction perpendicular to the first horizontal direction; and
a driving portion provided to be movable in the first horizontal direction along the at least one guide rail, the driving portion configured to grip at least one selected shelf from among the plurality of shelves and to move, in the first horizontal direction, one or more shelves that are engaged to each other by respective first couplers and respective second couplers, the one or more shelves comprising the at least one selected shelf.

2. The storage apparatus of claim 1, further comprising:
a gas supply portion comprising a plurality of gas supply pipes coupled to the plurality of shelves and configured to supply a purge gas to the portion of the plurality of semiconductor devices stored in a carrier accommodated on each shelf of the plurality of shelves.

3. The storage apparatus of claim 2, wherein the plurality of gas supply pipes comprise flexible pipes configured to supply the purge gas based on the plurality of shelves sliding on the at least one guide rail.

4. The storage apparatus of claim 1, wherein the plurality of frames comprises a lower frame and an upper frame stacked on the lower frame,
wherein the at least one selected shelf comprises a plurality of shelves disposed in the vertical direction on the lower frame and the upper frame, and
wherein the plurality of shelves slide together with each other in the first horizontal direction.

5. The storage apparatus of claim 1, wherein lowermost shelves disposed on a lowermost frame, from among the plurality of frames, are fixed so as to prevent movement in the first horizontal direction.

6. The storage apparatus of claim 5, wherein a first number of shelves disposed on frames stacked on the lowermost frame is smaller than a second number of the lowermost shelves disposed on the lowermost frame.

7. The storage apparatus of claim 1, wherein each of the first couplers comprises a permanent magnet, and
wherein each of the second couplers comprises an electromagnet.

8. The storage apparatus of claim 1, further comprising:
a plurality of sensors provided on the upper surfaces of the plurality of shelves configured to determine whether other shelves from among the plurality of shelves are arranged in the vertical direction.

9. The storage apparatus of claim 1, wherein the driving portion is further configured:
to move at a predetermined speed;
to start to move at a gradually increasing speed; and
to stop moving at a gradually decreasing speed.

10. The storage apparatus of claim 1, further comprising:
elastic members provided on the first side surface and the second side surface of each shelf of the plurality of shelves, the elastic members configured to absorb an impact from other shelves from among the plurality of shelves.

11. A storage system for a plurality of semiconductor devices, comprising:
a driving rail extending in a first horizontal direction;
a storage apparatus extending along the driving rail, the storage apparatus configured to accommodate the plurality of semiconductor devices; and
a transport device movable on the driving rail, the transport device configured to load the plurality of semiconductor devices to the storage apparatus and to unload the plurality of semiconductor devices from the storage apparatus,
wherein the storage apparatus comprises:
a plurality of frames stacked at least partially on top of one another in a vertical direction, each frame of the plurality of frames comprising at least one guide rail extending in the first horizontal direction, each frame of the plurality of frames comprising an opening portion opened in the vertical direction, the transport device being configured to pass through the opening portion to move between the plurality of frames;
a plurality of shelves provided to be slidably movable on the plurality of frames along the at least one guide rail, each shelf of the plurality of shelves configured to accommodate a portion of the plurality of semiconductor devices on an upper surface of the shelf;
a coupling portion comprising first couplers and second couplers that are selectively engaged with each other by an external control signal, the first couplers provided on a first side surface of each shelf of the plurality of shelves, the second couplers provided on a second side surface of each shelf of the plurality of shelves, the second side surface being opposite to the first side surface, the first side surface and the second side surface extending along a second horizontal direction perpendicular to the first horizontal direction; and
a driving portion provided to be movable in the first horizontal direction along the at least one guide rail, the driving portion configured to grip at least one selected shelf from among the plurality of shelves and to move, in the first horizontal direction, one or more shelves that are engaged to each other by respective first couplers and respective second couplers, the one or more shelves comprising the at least one selected shelf.

12. The storage system of claim 11, wherein the storage apparatus further comprises:
a gas supply portion comprising a plurality of gas supply pipes coupled to the plurality of shelves and configured to supply a purge gas to the portion of the plurality of semiconductor devices stored in a carrier accommodated on each shelf of the plurality of shelves.

13. The storage system of claim 12, wherein the plurality of gas supply pipes comprise flexible pipes configured to supply the purge gas based on the plurality of shelves sliding on the at least one guide rail.

14. The storage system of claim 11, wherein the plurality of frames comprise a lower frame, and an upper frame stacked on the lower frame,
wherein the at least one selected shelf comprises a plurality of shelves disposed in the vertical direction on the lower frame and the upper frame, and
wherein the plurality of shelves slide together with each other in the first horizontal direction.

15. The storage system of claim 11, wherein lowermost shelves disposed on a lowermost frame, from among the plurality of frames, are fixed so as to prevent movement in the first horizontal direction.

16. The storage system of claim 15, wherein a first number of shelves disposed on frames stacked on the lowermost frame is smaller than a second number of the lowermost shelves disposed on the lowermost frame.

17. The storage system of claim 11, wherein the storage apparatus further comprises:
a plurality of sensors provided on the upper surfaces of the plurality of shelves configured to determine whether other shelves from among the plurality of shelves are arranged in the vertical direction.

18. The storage system of claim 11, wherein the driving portion is further configured:
to move at a predetermined speed;
to start to move at a gradually increasing speed; and
to stop moving at a gradually decreasing speed.

19. The storage system of claim 11, wherein the storage apparatus further comprises:
elastic members provided on the first side surface and the second side surface of each shelf of the plurality of shelves, and configured to absorb an impact from other shelves from among the plurality of shelves.

20. A storage apparatus for a plurality of semiconductor devices, comprising:
a plurality of frames, each frame of the plurality of frames comprising a guide rail extending in a horizontal direction and a driving portion movable along the guide rail, the plurality of frames being stacked at least partially on top of each other in a vertical direction;
a plurality of shelves configured to accommodate the plurality of semiconductor devices on upper surfaces of the plurality of shelves, and configured to be slidably movable along the guide rail through the driving portion of each frame of the plurality of frames, each shelf of the plurality of shelves comprising a permanent magnet on a first side surface and an electromagnet on a second side surface opposite to the first side surface; and
a gas supply portion comprising a plurality of gas supply pipes coupled to the plurality of shelves and configured to supply a purge gas to the plurality of semiconductor devices,
wherein one or more shelves selected from among the plurality of shelves disposed adjacent to each other are engaged to each other through the permanent magnet and the electromagnet to slidably move together in the horizontal direction, and
wherein a plurality of second shelves disposed on the one or more selected shelves slidably move in the horizontal direction together with the one or more selected shelves.
